(19) United States
(12) Patent Application Publication
(10) Pub. No.: US 2002/0081825 A1
(43) Pub. Date: Jun. 27, 2002

(54) Method for reproducibly forming a predetermined quantum dot structure and device produced using same

(76) Inventors: Robin L. Williams, Orleans (CA); Jacques Lefebvre, Ottawa (CA); Philip Poole, Ottawa (CA); Geoffrey C. Aers, Orleans (CA); Charles Lacelle, Orleans (CA); Jeffrey W. Fraser, Orleans (CA)

Correspondence Address: FREEDMAN & ASSOCIATES, 117 CENTREPOINTE DRIVE, SUITE 350, NEPEAN, ONTARIO, K2G 5X3, CA

(21) Appl. No.: 09/984,116

(22) Filed: Oct. 29, 2001

Related U.S. Application Data
(60) Provisional application No. 60/256,925, filed on Dec. 21, 2000.

(51) Int. Cl. H01L 21/20

(52) U.S. Cl. 438/493

(57) ABSTRACT

The present invention relates to a method for reproducibly forming a predetermined quantum dot structure and a device produced using same. A crystal facet of a substrate base is patterned for providing a predetermined portion of the crystal facet for subsequent predetermined crystal growth. A first growth material is deposited for crystallographically growing a predetermined mesa structure on the predetermined portion of the crystal facet. The mesa structure, which is a portion of the quantum dot structure, comprises predetermined low index side facets and a predetermined top surface. A second growth material for forming at least a quantum dot on the mesa structure is then deposited. The number, the lateral dimensions and the location of the at least a quantum dot is determined by the mesa structure. A sufficient amount of the second growth material is deposited such that a sufficient thickness for Straski-Krastinow growth of the second growth material on the top surface of the mesa structure is exceeded. The at least a quantum dot is embedded by continuing crystal growth on the mesa structure. The method allows reproducible manufacture of predetermined quantum dot structures such as single photon sources. For example, a covering structure is crystallographically grown in-situ on the mesa structure wherein the covering structure comprises crystal facets forming a mirror. The covering structure then forms together with the mesa structure and a reflector of the substrate base a micro-cavity providing a single photon laser.

This application claims priority from U.S. Provisional Patent Application No. 60/256,925 filed Dec. 21, 2000.

### FIELD OF THE INVENTION

The present invention relates to a method of forming quantum dot structures, particularly to a method for reproducibly forming a predetermined quantum dot structure in-situ during crystal growth.

### BACKGROUND OF THE INVENTION

With the advances of modern information technology, a steadily increasing amount of data has to be processed and transmitted at increasing speeds in numerous applications. The development of conventional electronic devices has already reached the physical limits of these systems in some applications. In order to extend processing and transmission capabilities new methods based on new physical principles must be used to overcome the limits of the present technology. One limitation of the conventional technology has been overcome with the introduction of fiber optical networks for data transmission, increasing the transmission capability and speed by several orders of magnitude. However, the present fiber optical technology is itself limited by the characteristics of present semiconductor lasers, so-called bulk crystal lasers.

In a bulk crystal where there is no confinement of carriers, it is well known that the density of states of the carriers increases continuously and parabolically with energy. As a result, emitted light has a relatively wide spectral range and is noisy as a result of thermal fluctuations.

In a quantum well structure, where carriers are constrained to move in a plane, discrete quantum levels appear as is well known in the art. In such a case, the density of states of the carriers changes stepwise. Because of such restrictions imposed on the distribution of the carriers, a quantum well structure provides a narrower emission spectrum when used for an optical semiconductor device such as a laser diode, and the efficiency of laser oscillation is improved.

In a quantum dot structure, where the degree of carrier confinement is increased further, the density of states becomes discrete in correspondence to the discrete quantum levels. A system having such a discrete energy spectrum, in which transition of carriers occurs only discontinuously or stepwise, provides a very sharp spectrum when used for an optical semiconductor device even in a room temperature environment where the carriers experience substantial thermal excitation.

Quantum dot structures emitting light in the wavelength regime between 1.3,μm and 1.55 μm would provide the basis for further increasing data transmission rates for long distance communications by several orders of magnitude. Furthermore, it would enable the realization of new information technologies such as quantum computing and quantum cryptography.

Numerous methods for producing quantum dot structures based on methods used for manufacturing conventional semiconductor devices such as electron beam lithography, etching, epitaxy or ion beam implantation are discussed in the following references, which are hereby incorporated by reference:

Ugajin in U.S. Pat. No. 5,229,320 issued Jul. 20, 1993 combining electron beam diffraction, epitaxial growth and dry etching;

Kato in U.S. Pat. No. 5,532,184 issued Jul. 2, 1996 combining epitaxially growth and ion beam implantation;

Bestwick et al. in U.S. Pat. No. 5,571,376 issued Nov. 5, 1996 based on etching;

Petroff et al. in U.S. Pat. No. 5,614,435 issued Mar. 25, 1997 photolithography;

Ro et al. in U.S. Pat. No. 6,033,972 issued Mar. 7, 2000 using chemical beam epitaxy;

Ro et al. in U.S. Pat. No. 6,074,936 issued Jun. 13, 2000 combining photolithography and chemical wet etching; and,

Oliver Benson, Charles Santori, Matthew Pelton, and Yoshihisa Yamamoto: “Regulated and Entangled Photons from a Single Quantum Dot,” Physical Review Letters, Vol. 84, #11, pp 2513, 2000.

All these prior art methods that work perfectly in conventional semiconductor technology have numerous drawbacks when applied to the production of quantum effect devices. Here, a nano-structure having a size almost equal to the quantum mechanical wavelength of electrons has to be formed on a semiconductor substrate to control the wave motion of electrons. Unfortunately, the prior art methods experience huge difficulties in properly producing ex-situ substrate mesa structures and in positioning quantum dots on these structures at predetermined locations using the above mentioned technologies resulting, for example, in a random distribution of the quantum dots during etching or epitaxy. Furthermore, methods based on electron beams or ion beams are affected by scattering effects of the electrons or ions in the crystal lattice resulting in a defected quantum dot structure. These various kinds of defects induced during production substantially decrease the quantum characteristics of the device and do not allow reproducible manufacturing of such devices.

Furthermore, these prior art methods require very long processing times and are generally not applicable for manufacturing quantum dot structures in large quantities.

It is, therefore, an object of the invention to overcome the drawbacks of the prior art and to provide a method for reproducibly producing predetermined quantum structures.

It is another object of the invention to provide a method wherein the nano-template and the quantum dots are produced in-situ during crystal growth.

### SUMMARY OF THE INVENTION

In accordance with the present invention there is provided a method for reproducibly forming a predetermined quantum dot structure comprising the steps of:

providing a substrate base, the substrate base having at least one crystal facet;

patterning a crystal facet of the at least one crystal facets for providing a predetermined portion of the crystal facet for subsequent predetermined crystal growth;

depositing a first growth material for crystallographically growing a predetermined mesa structure on the predetermined portion of the crystal facet, the mesa structure being a portion of the quantum dot structure; and,

depositing a second growth material for forming a predetermined at least a quantum dot on the mesa structure, wherein the number, the lateral dimensions and the location of the at least a quantum dot result from the mesa structure.

In accordance with the present invention there is further provided a method for reproducibly forming a predetermined quantum dot structure comprising the steps of:

providing a substrate base, the substrate base having at least one crystal facet;

patterning a crystal facet of the at least one crystal facets for providing a predetermined portion of the crystal facet for subsequent predetermined crystal growth;

depositing a first growth material for crystallographically growing a predetermined mesa structure on the predetermined portion of the crystal facet, wherein the mesa structure comprises predetermined low index side facets and a predetermined top surface, the mesa structure being a portion of the quantum dot structure;

depositing a second growth material for forming at least a quantum dot, wherein the number, the lateral dimensions and the location of the at least a quantum dot result from the width and shape of the predetermined top surface of the mesa structure, and wherein a sufficient amount of the second growth material is deposited such that a sufficient thickness for Straski-Krastinow growth of the second growth material on the top surface is exceeded; and,

embedding the at least a quantum dot by continuing crystal growth on the mesa structure, wherein the crystal growth is continued by depositing a growth material other than the second growth material.

In accordance with an aspect of the present invention there is provided a predetermined quantum dot structure comprising:

at least a quantum dot for emitting electromagnetic radiation in an atom like fashion; and,

a predetermined mesa structure crystallographically grown on a patterned crystal facet of a substrate base for reproducibly determining the formation of the at least a quantum dot thereupon, wherein the number, the lateral dimensions and the location of the at least a quantum dot result from the mesa structure, and wherein the at least a quantum dot is grown in-situ on the mesa structure by depositing a growth material other than a growth material of the mesa structure.

In accordance with the aspect of the present invention there is further provided a predetermined quantum dot structure comprising:

at least a quantum dot for emitting electromagnetic radiation in an atom like fashion;

a predetermined mesa structure crystallographically grown on a patterned crystal facet of a substrate base, the substrate base comprising a reflector, for reproducibly determining the formation of the at least a quantum dot thereupon, the mesa structure having a predetermined top surface, wherein the number, the lateral dimensions and the location of the at least a quantum dot result from the width and shape of the predetermined top surface of the mesa structure, and wherein the at least a quantum dot is grown in-situ on the mesa structure by depositing a growth material other than a growth material of the mesa structure; and,

a covering structure for embedding the at least a quantum dot, the covering structure crystallographically grown in-situ on the mesa structure and the at least a quantum dot by depositing a growth material other than the growth material of the quantum dot, wherein the covering structure comprises crystal facets forming a mirror, and wherein the covering structure together with the mesa structure and the reflector of the substrate base form a micro-cavity such that the at least a quantum dot is placed at a position for maximum field amplitude within the micro-cavity.

### BRIEF DESCRIPTION OF FIGURES

Exemplary embodiments of the invention will now be described in conjunction with the following drawings, in which:

FIG. 1 is a simplified flow diagram of a method according to the invention for reproducibly forming a predetermined quantum dot structure;

FIG. 2 is a simplified block diagram illustrating various predetermined openings on a patterned substrate surface used in the method shown in FIG. 1;

FIG. 3 illustrates an undercut mesa stripe according to the invention surrounding a predetermined opening;

FIG. 4a illustrates a mesa structure grown using the method shown in FIG. 1;

FIG. 4b illustrates a mesa structure grown using the method shown in FIG. 1;

FIG. 5 illustrates a mesa structure with quantum dots grown using the method shown in FIG. 1;

FIG. 6 is a is a simplified block diagram of a single photon source formed using the method shown in FIG. 1; and,

FIG. 7 is a simplified block diagram of a quantum dot array laser formed using the method shown in FIG. 1.

### DETAILED DESCRIPTION OF PREFERRED EMBODIMENTS

Self-assembled quantum dot nanostructures have been realized in a large number of strained semiconductor materials systems using a variety of crystal growth techniques. For systems based on Stranski-Krastanow growth, quantum dot formation is typically achieved following the deposition of a thin (5-10 Å) wetting layer. The wetting layer is commensurate with the underlying semiconductor substrate and has an elastic strain energy that increases approximately linearly with wetting layer thickness. It has been shown that quantum dot formation is a strain driven process in which the increasing strain energy associated with the 2D wetting layer is partially offset by the formation of 3D islands and the consequent redistribution of strain between island and substrate. In addition to the strain redistribution, which acts to lower the total energy, the island formation is necessarily accompanied by the formation of surface facets increasing the total energy of the system. For Stranski-Krastanow growth on planar substrates quantum dot nucleation is random across the plane.

For many device applications, it would be advantageous to be able to control the nucleation sites for quantum dots and to control the size and electronic structure of individual dots.

Since self-assembled quantum dot nucleation is a process driven by the energetics of strain relaxation, control of the nucleation process is based on controlling the semiconductor composition and consequently the elastic strain. Control of semiconductor composition has been successfully demonstrated for InGaAs material on patterned substrates. The substrates are typically wet etched prior to crystal growth to introduce low index crystal facets on which the indium adatom migration length is large compared to that on adjacent orientations. Surface diffusion away from the low index facets onto the adjacent areas of the substrate is then used to influence quantum dot nucleation in a manner controlled through the geometry of the etched structure. However, these techniques suffer from a number of disadvantages. Since the surface diffusion process is very sensitive to the geometry and surface quality of the etched structure, the structure must be produced very accurately using a wet etch processing procedure. This is extremely difficult to achieve if angles, depths and widths of the etched structures have to be controlled simultaneously making it almost impossible to reproducibly generate the local changes in the semiconductor composition for predetermined quantum dot nucleation. Furthermore, it is very difficult to include strain fields in the ex situ prepared structures.

The quantum dot formation technique according to the invention as described in the following overcomes these problems by forming a template for the quantum dot nucleation in situ using crystal growth techniques. The technique according to the invention allows production of very precise quantum dot structures of reproducible quality. Furthermore, the technique allows the insertion of a predetermined number of strained quantum wells at predetermined locations during growth of the patterned substrate template.

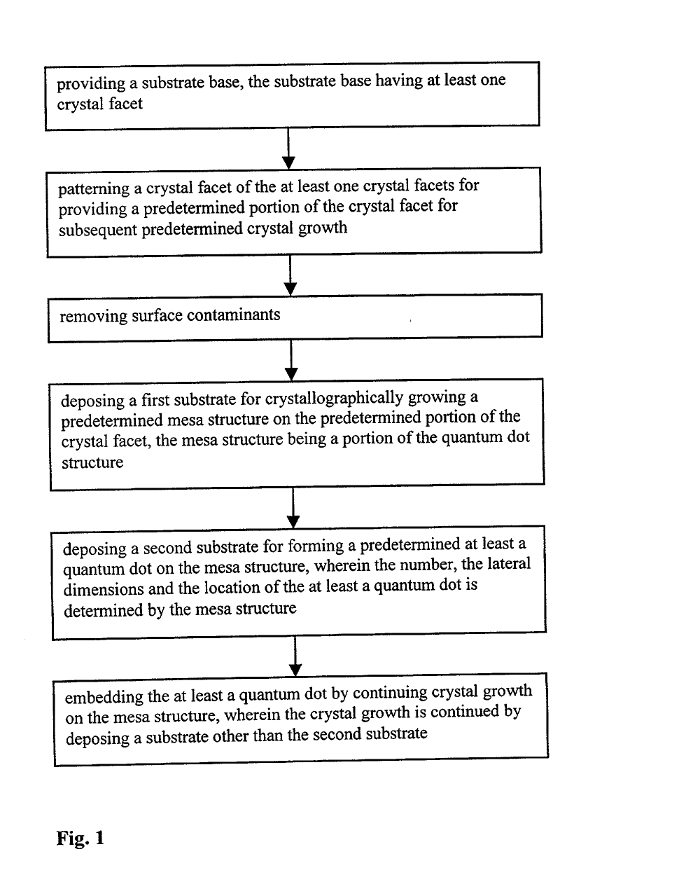

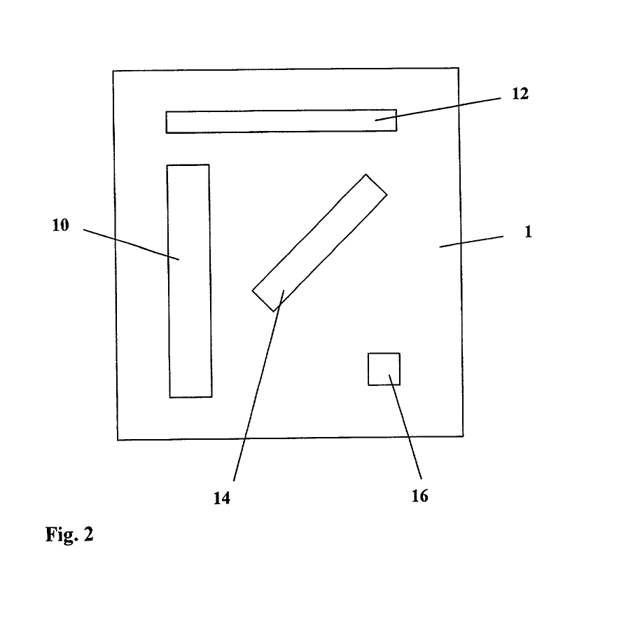

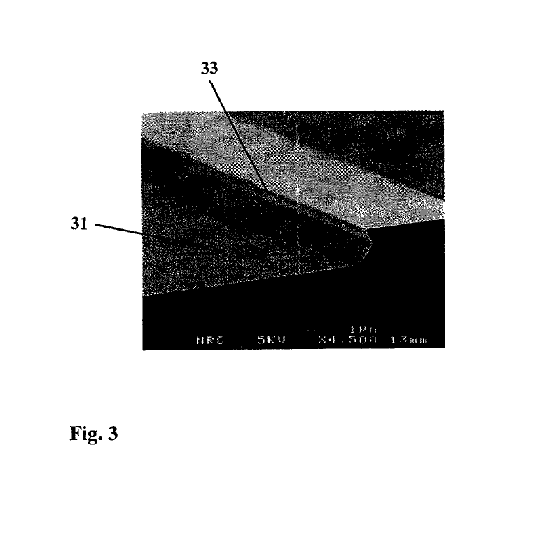

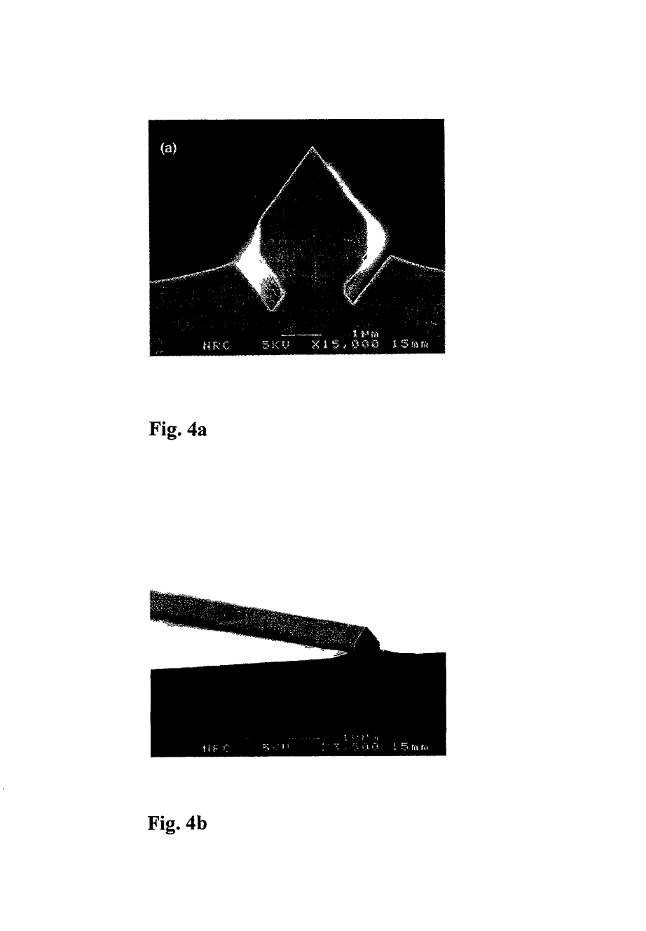

In the following the quantum dot formation technique according to the invention will be described with respect to the formation of an InAs quantum dot on an InP template. As is obvious to persons of skill in the art, this technique is described using one combination of materials for simplicity but is not limited thereto. It is evident that this technique is also applicable using numerous other materials such as, for example, InAs/GaAs or ternery and quaternary combinations of these or other materials. FIG. 1 shows a simplified flow diagram of a method for reproducibly forming a predetermined quantum dot structure according to the invention. Prior to crystal growth, an exactly oriented surface, for example, a (001) surface of an InP substrate is patterned. For simplicity, the following examples are based on crystal growth on a (001) surface. Optionally, other substrates, for example, a substrate forming a Bragg reflector and, further optionally, other crystal surfaces of a substrate are used. The substrate is patterned using, for example, chemically assisted ion beam etching or selective oxide patterning for providing an oxide layer such as SiO₂ deposited on the InP substrate, the oxide layer having predetermined openings therein. During InP template growth and subsequent dot deposition, growth only occurs inside the patterned openings. The shape and orientation of the predetermined openings, as shown in FIG. 2, directly influences the InP template growth, producing various shapes of the grown template. For example, FIG. 2 shows 3 lines of various widths—normally between 200 and 1000 nm—along the (110) direction 10, along the (1\overline{1}0) direction 12, and along the (100) direction 14, as well as a square shaped opening 16 on a (001) surface of an InP substrate. Crystal growth in these openings results in ridge structures or a pyramidal structure, respectively. Alternatively, the portions of the substrate surface dedicated for template growth are covered by an oxide layer. Using a dry etching technique, substrate material is removed from the remaining substrate surface area not covered by the oxide layer creating undercut mesa stripes for subsequent template growth after removal of the oxide layer. FIG. 3 illustrates in a cross sectional view an undercut mesa stripe 33. The undercut mesa stripes result in a geometry that effectively isolates the growth of the mesa structure from any effects occurring on the remainder of the substrate. Subsequent growth of InP produces high quality {111} B or {011} facets depending upon the orientation of the sides of the mesa structure, as shown in FIGS. 4a and 4b, and on the orientation of the substrate surface. The appearance of low index side facets along the mesa structure edges results from a varying growth rate for the various crystallographic planes. More specifically, the growth rate is lower on low surface energy planes, producing a large population of surface adatoms available for surface diffusion to adjacent higher growth rate facets. Prior to full completion of the low index side facets deposited material migrates to the (001) top surface of the mesa structure. The diffusion of source material away from the low growth facets is used here to reduce the lateral dimensions of the mesa structure during crystal growth and to produce nano-scale templates for the quantum dot formation. The mesa structures are substantially free of process induced defects since they are formed entirely during the growth process. A perfect mesa structure is even obtained from a mask with opening having imperfect edges. Because such facets are crystallographically determined the angle and resulting surface diffusion properties are highly reproducible, whilst the facet length is accurately determined through the growth time. All that is required to tightly control the mesa structure geometry is an accurate knowledge of the initial width of the opening prior to growth. This is generally achieved by calibrating the etching process or, if necessary, by precisely measuring the width using scanning electron microscopy. Depending on the width of the opening and the growth time, i.e. the amount of deposited material, the mesa structure has a top surface (001) of a predetermined width. With increasing growth time the facet length increases resulting in a decrease of the width of the top surface, which will eventually be eliminated leaving a mesa structure with a fully developed triangular cross section as shown in FIG. 4a. Prior to growth possible surface contaminants are removed using, for example, a slow InP wet etch (H₃PO₄:H₂O₂:H₂O 1:1:10, 3 nm/min). The crystal growth of the InP is performed, for example, at 500° C. with a growth rate of 0.5,μm/h, using trimethyl-indium and cracked PH₃ as sources. Of course numerous other processes may be used for removing surface contaminants and template growth material deposition.

Optionally, the mesa structure comprises a plurality of layers of different composition by varying the materials deposited during crystal growth.

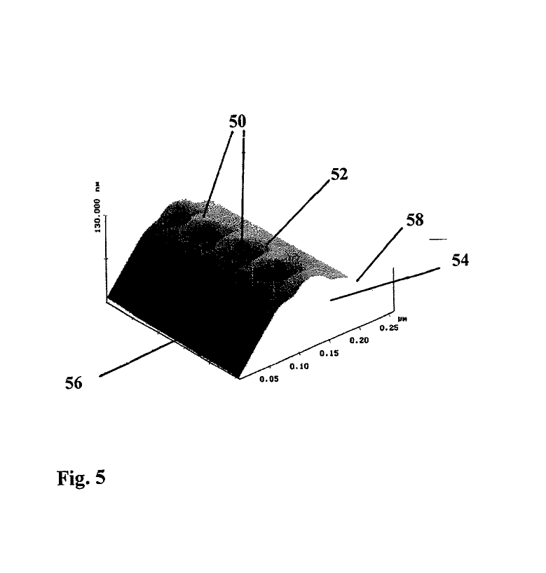

Following the growth process of the InP template, sufficient InAs is deposited to exceed the critical thickness for Straski-Krastinow growth on the (001) top surface of the mesa structure. Quantum dot formation, quantum dot size, quantum dot density and location of quantum dots depend on the mesa structure geometry and the amount of deposited growth material. This allows one to manufacture a predetermined quantum dot structure by controlling the mesa structure geometry and the amount of deposited growth material. Herein incorporated is also material migrating from the facets of the mesa structure. The migration results from the same diffusion process as the migration of the InP described above. The InAs is deposited using, for example, trimethyl-indium and cracked AsH₃ as sources at 500° C. with a growth rate of 0.5,μm/h. As shown in FIG. 5, the quantum dot nucleation based on Straski-Krastinow growth produces a string of quantum dots 50 on the (001) top surface 52 of the mesa structure 54, a ridge having a trapezoidal cross section and a width at the top of approximately 20 nm. No dots have been observed either on the mesa structure facets 56, 58 or on the oxide layer surrounding the mesa structure in numerous experiments. Furthermore, the quantum dots 50 are uniform in size and spacing. The quantum dots 50 have approximately equal lateral dimensions in directions parallel and perpendicular to the longitudinal extension of the top surface 52, wherein the lateral dimensions of the quantum dots are limited by the width of the (001) top surface 52.

Continuation of the crystal growth process allows embedding the quantum dot. Crystal growth is continued with InP embedding the InAs quantum dot within InP or, alternatively with another growth material or, further alternatively with various layers of different growth materials. This allows, for example, a reproducible manufacture of a predefined quantum dot at a predefined location within a micro-cavity providing a single photon source completely produced in-situ during crystal growth.

Optionally, control of quantum dot formation is possible through the use of one or more embedded quantum well stressors. Quantum well stressors are layers of lattice mismatched materials such as InGaAs embedded into the mesa structure during crystal growth producing a strain field impacting on the self assembled dot growth on the facets of the mesa structure. Appropriate number, dimension and location of the quantum well stressors cause the self assembled dots on the facets to migrate to a predefined location forming quantum dots having a predetermined lateral dimension at predetermined locations. More detailed information concerning quantum well stressors has been disclosed by the inventors in: R. L. Williams et al., Journal of Crystal Growth 223 (2001) 321-331, which is incorporated hereby for reference.

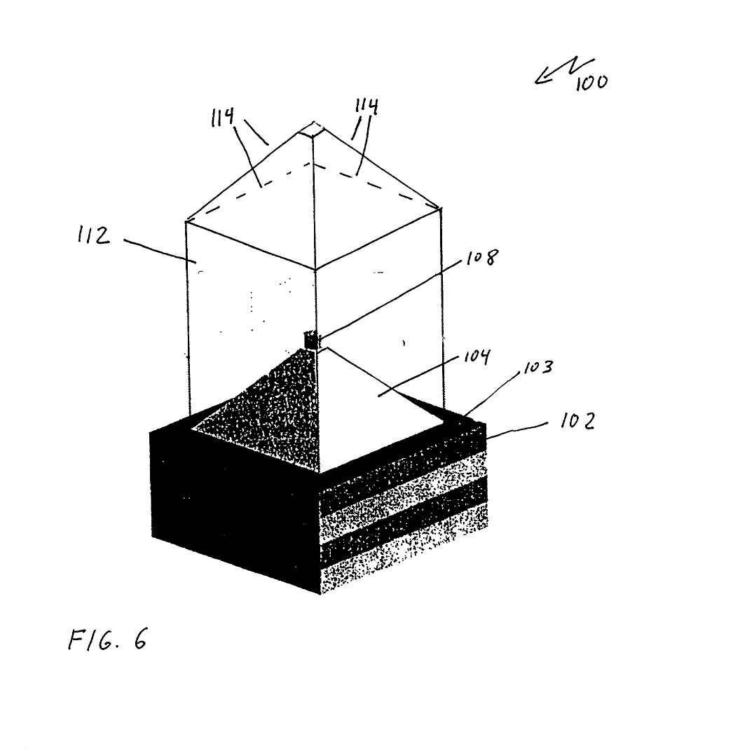

The method for forming a predetermined quantum dot structure of reproducible quality according to the invention provides means for a reproducible manufacture of single photon sources, which are essential for quantum cryptography, and advanced laser sources for optical telecommunications depending on the reduced inhomogeneous line width provided by ordered quantum dot arrays. Referring to FIG. 6 a predetermined quantum dot structure 100, forming a single photon source, according to the invention is shown. The quantum dot structure 100 comprises a mirror 102 in the form of a Bragg reflector that is deposited prior to the main growth on a planar semiconductor substrate such as a (001) surface. Prior to template growth a (001) surface 103, of the Bragg reflector is patterned such that a predetermined square based pyramid 104 is formed as a mesa structure during crystal growth. Deposition of growth material such as InP results in subsequent growth of the mesa structure 104 comprising four naturally formed intersecting {110} crystal facets, which lie at an angle of 45° to the (001) substrate surface 103. At a predetermined instance of the growth process growth material such as InAs is deposited resulting in the formation of a quantum dot. The crystal growth of the pyramidal mesa structure stops leaving a 200Å×200 Å(001) top surface at the apex of the mesa structure 104 forming a truncated pyramid, which defines the lateral dimensions of the quantum dot 108. The quantum dot 108 is subsequently buried by further crystal growth due to deposition of InP. After termination of the crystal growth at a predetermined time instance the quantum dot structure 100 comprises two mirrors 102 and 114 separated by a pillar structure 112 developed in-situ during crystal growth. The mirror 114 at the top of the pillar is formed naturally during the crystal growth and consists of four intersecting (110) crystal facets 114. The facets 114, which lie at 45° to the (001) substrate surface form a natural high quality reflector and obviate the necessity to grow a second Bragg reflector mirror. Optionally, the facets 114 are HR coated after growth to increase the cavity quality factor. Further optionally, a Bragg reflector is provided on the facets 114. Timing to terminate the various manufacturing steps of the quantum dot structure 100 is determined, for example, by a calibration process providing knowledge about the rate of the various crystal growth processes. The timing allows exact placement of a laser gain medium—quantum dot—at the position for maximum field amplitude within the micro-cavity 112.

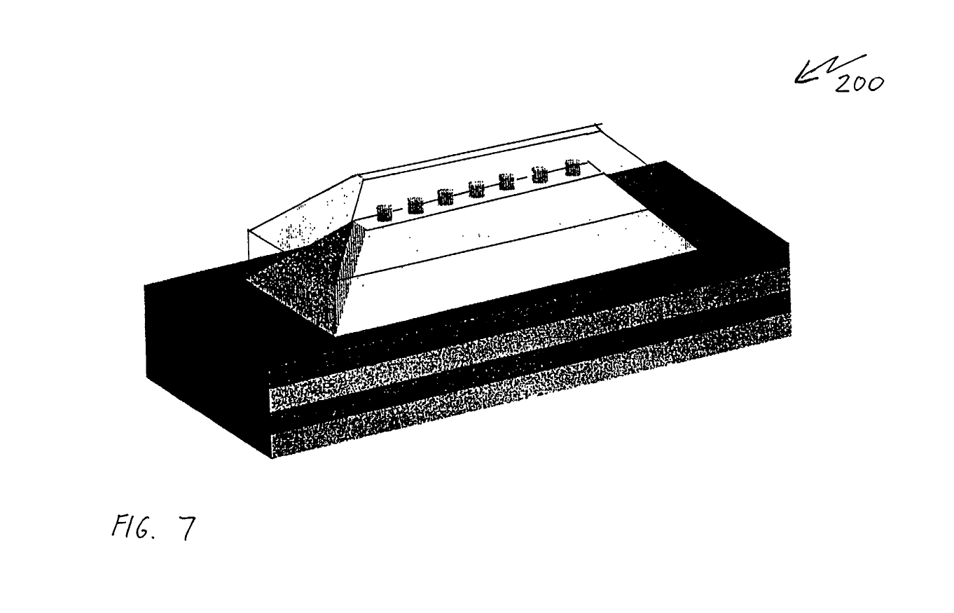

FIG. 7 illustrates another embodiment of a predetermined quantum dot structure 200 according to the invention. A linear quantum dot array laser source 200 is provided based on a ridge like mesa structure manufactured using the method according to the invention as described above.

The quantum dot structures described above with respect to FIGS. 6 and 7 emit light in the wavelength regimes between 1.3 μm and 1.55 μm. Being reproducibly manufactured with high accuracy these quantum dot structures provide the basis for further increasing data transmission rates for long distance communications by several orders of magnitude and enable the realization of new information technologies such as quantum computing and quantum cryptography.

As is evident, variation of numerous parameters allows manufacture of various predetermined quantum dot structures. Some of these parameters are, for example, different growth materials used for growing the mesa structures, different growth materials used for growing the quantum dots, different growth times for growth material deposition, different substrate surfaces for growing the mesa structure. After a calibration process it is possible to reproducibly manufacture predetermined quantum dot structures because all the main components of the quantum dot structure are produced in-situ and are crystallographically determined. All that is required to tightly control the mesa structure geometry and, therefore, the quantum dot location is an accurate knowledge of the initial width of the opening prior to growth. The mesa structures are substantially free of process induced defects since they are formed entirely during the crystal growth process. A perfect mesa structure is even obtained from a mask with an opening having imperfect edges.

Numerous other embodiments of the invention will be apparent to persons skilled in the art without departing from the spirit and scope of the invention as defined in the appended claims.

What is claimed is:

1. A method for reproducibly forming a predetermined quantum dot structure comprising the steps of:
providing a substrate base, the substrate base having at least one crystal facet;
patterning a crystal facet of the at least one crystal facets for providing a predetermined portion of the crystal facet for subsequent predetermined crystal growth;
depositing a first growth material for crystallographically growing a predetermined mesa structure on the predetermined portion of the crystal facet, the mesa structure being a portion of the quantum dot structure; and,
depositing a second growth material for forming a predetermined at least a quantum dot on the mesa structure, wherein the number, the lateral dimensions and the location of the at least a quantum dot result from the mesa structure.

2. A method for reproducibly forming a predetermined quantum dot structure as defined in claim 1, comprising the step of removing surface contaminants.

3. A method for reproducibly forming a predetermined quantum dot structure as defined in claim 2, wherein the substrate base comprises the same material as the first growth material.

4. A method for reproducibly forming a predetermined quantum dot structure as defined in claim 3, wherein the first growth material is a semiconductor material.

5. A method for reproducibly forming a predetermined quantum dot structure as defined in claim 4, comprising the step of embedding the at least a quantum dot by continuing crystal growth on the mesa structure, wherein the crystal growth is continued by depositing a growth material other than the second growth material.

6. A method for reproducibly forming a predetermined quantum dot structure as defined in claim 5, comprising the step of embedding a quantum well stressor within the mesa structure during crystal growth of the same.

7. A method for reproducibly forming a predetermined quantum dot structure as defined in claim 6, wherein the quantum well stressor is embedded by depositing a growth material other than the first growth material for forming a layer of the growth material within the mesa structure.

8. A method for reproducibly forming a predetermined quantum dot structure as defined in claim 7, wherein the deposition of the growth material other than the first growth material is predetermined such that the layer of the growth material comprises a predetermined thickness and is placed at a predetermined location within the mesa structure.

9. A method for reproducibly forming a predetermined quantum dot structure as defined in claim 4, wherein the step of patterning a crystal facet comprises the step of depositing an oxide layer on the crystal facet on portions of the crystal facet other than the predetermined portion for subsequent crystal growth.

10. A method for reproducibly forming a predetermined quantum dot structure as defined in claim 9, wherein the predetermined portion for subsequent crystal growth comprises a rectangular portion of the crystal facet.

11. A method for reproducibly forming a predetermined quantum dot structure as defined in claim 10, wherein the rectangular portion is aligned in predetermined directions with respect to the crystal facet.

12. A method for reproducibly forming a predetermined quantum dot structure as defined in claim 4, wherein the step of patterning a crystal facet comprises the steps of:
depositing an oxide layer on the predetermined portions for subsequent crystal growth;
wet etching portions of the crystal facet other than the predetermined portions for subsequent crystal growth; and,
removing the oxide layer.

13. A method for reproducibly forming a predetermined quantum dot structure comprising the steps of:
providing a substrate base, the substrate base having at least one crystal facet;
patterning a crystal facet of the at least one crystal facets for providing a predetermined portion of the crystal facet for subsequent predetermined crystal growth;
depositing a first growth material for crystallographically growing a predetermined mesa structure on the predetermined portion of the crystal facet, wherein the mesa structure comprises predetermined low index side facets and a predetermined top surface, the mesa structure being a portion of the quantum dot structure;
depositing a second growth material for forming at least a quantum dot, wherein the number, the lateral dimensions and the location of the at least a quantum dot result from the width and shape of the predetermined top surface of the mesa structure, and wherein a sufficient amount of the second growth material is deposited such that a sufficient thickness for Straski-Krastinow growth of the second growth material on the top surface is exceeded; and,
embedding the at least a quantum dot by continuing crystal growth on the mesa structure, wherein the crystal growth is continued by depositing a growth material other than the second growth material.

14. A method for reproducibly forming a predetermined quantum dot structure as defined in claim 13, wherein the substrate base comprises a Bragg reflector.

15. A method for reproducibly forming a predetermined quantum dot structure as defined in claim 14, wherein the lateral dimensions of the mesa structure are reduced during crystal growth due to diffusion of source material away from the low index side facets.

16. A method for reproducibly forming a predetermined quantum dot structure as defined in claim 15, wherein the sufficient amount of the second growth material includes material migrating from the facets of the mesa structure to the top surface.

17. A method for reproducibly forming a predetermined quantum dot structure as defined in claim 15, wherein the mesa structure is determined by the shape of the predetermined portion of the patterned crystal facet.

18. A method for reproducibly forming a predetermined quantum dot structure as defined in claim 17, wherein the mesa structure is determined by the orientation of the predetermined portion with respect to the patterned crystal facet.

19. A method for reproducibly forming a predetermined quantum dot structure as defined in claim 18, wherein the predetermined mesa structure is obtained by terminating depositing of the first growth material at a predetermined time instance based on a growth rate of the crystal growth process.

20. A predetermined quantum dot structure comprising:
at least a quantum dot for emitting electromagnetic radiation in an atomlike fashion; and,
a predetermined mesa structure crystallographically grown on a patterned crystal facet of a substrate base for reproducibly determining the formation of the at least a quantum dot thereupon, wherein the number, the lateral dimensions and the location of the at least a quantum dot result from the mesa structure, and wherein the at least a quantum dot is grown in-situ on the mesa structure by depositing a growth material other than a growth material of the mesa structure.

21. A predetermined quantum dot structure as defined in claim 20, comprising a covering structure for embedding the at least a quantum dot, wherein the covering structure is crystallographically grown in-situ on the mesa structure by depositing a growth material other than the growth material of the quantum dot.

22. A predetermined quantum dot structure as defined in claim 21, wherein the mesa structure comprises a ridge having a triangular cross section.

23. A predetermined quantum dot structure as defined in claim 21, wherein the mesa structure comprises a pyramid.

24. A predetermined quantum dot structure as defined in claim 20, wherein the mesa structure comprises at least a quantum well stressor.

25. A predetermined quantum dot structure comprising:
at least a quantum dot for emitting electromagnetic radiation in an atomlike fashion;
a predetermined mesa structure crystallographically grown on a patterned crystal facet of a substrate base, the substrate base comprising a reflector, for reproducibly determining the formation of the at least a quantum dot thereupon, the mesa structure having a predetermined top surface, wherein the number, the lateral dimensions and the location of the at least a quantum dot result from the width and shape of the predetermined top surface of the mesa structure, and wherein the at least a quantum dot is grown in-situ on the mesa structure by depositing a growth material other than a growth material of the mesa structure; and,
a covering structure for embedding the at least a quantum dot, the covering structure crystallographically grown in-situ on the mesa structure and the at least a quantum dot by depositing a growth material other than the growth material of the quantum dot, wherein the covering structure comprises crystal facets forming a mirror, and wherein the covering structure together with the mesa structure and the reflector of the substrate base form a micro-cavity such that the at least a quantum dot is placed at a position for maximum field amplitude within the micro-cavity.

26. A predetermined quantum dot structure as defined in claim 25, wherein the mesa structure comprises a square based truncated pyramid.

27. A predetermined quantum dot structure as defined in claim 25, wherein the mesa structure comprises a ridge having a trapezoidal cross section.

28. A predetermined quantum dot structure as defined in claim 25, wherein the at least a quantum dot emits electromagnetic radiation in the form of light.

29. A predetermined quantum dot structure as defined in claim 28, wherein the at least a quantum dot emits light in the wavelength regimes between 1.3,μm and 1.55 μm.

30. A predetermined quantum dot structure as defined in claim 28, wherein the first growth material comprises InP.

31. A predetermined quantum dot structure as defined in claim 30, wherein the growth material of the quantum dot comprises InAs.
